(19) United States
(12) Patent Application Publication
(10) Pub. No.: US 2026/0123004 A1
(43) Pub. Date: Apr. 30, 2026

(54) FORMATION METHOD OF SEMICONDUCTOR STRUCTURE, SEMICONDUCTOR STRUCTURE, DEVICE AND ELECTRONIC APPARATUS

(71) Applicant: HANGZHOU FULLSEMI SEMICONDUCTOR CO., LTD., Hangzhou (CN)

(72) Inventors: Zongjin LAN, Hangzhou (CN); Guoshuai CHEN, Hangzhou (CN); Xiuzhu LI, Hangzhou (CN)

(73) Assignee: HANGZHOU FULLSEMI SEMICONDUCTOR CO., LTD., Hangzhou (CN)

(21) Appl. No.: 19/339,359

(22) Filed: Sep. 25, 2025

(30) Foreign Application Priority Data
Oct. 25, 2024 (CN) 2024115072985

(51) Int. Cl. H10D 64/01; H01L 21/3105; H01L 21/311

(52) U.S. Cl. CPC H10D 64/027; H10P 50/283; H10P 95/062

(57) ABSTRACT

The formation method of the semiconductor structure comprises: providing a substrate structure having a first trench; wherein the substrate structure comprises a base layer, an epitaxial layer, a first oxide layer, a hard mask layer and a second oxide layer arranged in sequence; the first trench penetrates through the first oxide layer, the hard mask layer and the second oxide layer, and a bottom of the first trench is located on the epitaxial layer; performing two etch-back processes on the hard mask layer of the substrate structure having the first trench and forming an isolation oxide layer on a surface of the first trench based on a thermal oxidation process between the two etch-back processes on the hard mask layer; forming an interlayer dielectric layer in the first trench to obtain a target semiconductor structure.

### FIELD OF THE INVENTION

The present invention relates to the field of semiconductor technology, and in particular to a formation method of a semiconductor structure, a semiconductor structure, a device and an electronic apparatus.

### BACKGROUND OF THE INVENTION

In the formation of a semiconductor device, trench formation is a common process. Following trench etching, an oxide layer is subsequently formed on the trench side wall to serve as an isolation layer. This isolation layer, being an essential processing step in the formation of the semiconductor device, plays a critical role in isolating interference between different process layers. The quality of this isolation layer directly impacts the film formation quality of subsequent layers and ultimately affects device performance, which has become a key research focus in the field.

In existing technologies, one approach combines thermal oxidation with deposition processes to form a composite oxide layer on the trench side wall. While this method reduces the bird beak effect, it involves complex processing and often introduces film stress issues. An alternative approach employs direct thermal oxidation to form the sidewall oxide layer, which simplifies the process and mitigates film stress. However, this method tends to induce the bird beak effect and hard mask eaves, leading to quality defects in subsequently formed material layers (e.g., void formation during filling) that ultimately degrade device performance. Consequently, there is an urgent technical need to develop a semiconductor manufacturing solution that can simultaneously minimize oxide film stress while mitigating the impacts of the bird beak effect and the hard mask eaves on subsequent processes.

### SUMMARY OF THE INVENTION

In order to solve the above technical problems, the present invention discloses, in one aspect, a formation method of a semiconductor structure, comprising: providing a substrate structure having a first trench; wherein the substrate structure comprises a base layer, an epitaxial layer, a first oxide layer, a hard mask layer and a second oxide layer arranged in sequence; the first trench penetrates through the first oxide layer, the hard mask layer and the second oxide layer, and a bottom of the first trench is located on the epitaxial layer; performing a first etch-back process on the hard mask layer to remove a portion of the hard mask layer adjacent to an opening of the first trench; forming an isolation oxide layer on a surface of the first trench based on a thermal oxidation process; performing a second etch-back process on the substrate structure having the isolation oxide layer to remove the second oxide layer, a portion of the first oxide layer and a portion of the isolation oxide layer and make a first side edge of the hard mask layer flush with a side wall of the first trench; and forming an interlayer dielectric layer in the first trench to obtain a target semiconductor structure.

In an exemplary embodiment, an etching amount of the hard mask layer in the first etch-back process is less than an etching amount of the hard mask layer in the second etch-back process.

In an exemplary embodiment, after the first etch-back process, the first side edge of the hard mask layer and a second side edge of the first oxide layer are recessed inward relative to the side wall of the first trench to expose a partial region of a top of the epitaxial layer; wherein the first side edge and the second side edge are side edges of the hard mask layer and the first oxide layer close to the side wall of the first trench, respectively.

In an exemplary embodiment, before performing the second etch-back process on the substrate structure having the isolation oxide layer, the method further comprises: performing a third etch-back process on the substrate structure having the isolation oxide layer to expose an end portion of the hard mask layer.

In an exemplary embodiment, a thickness of the second oxide layer after the third etch-back process is less than a thickness of the second oxide layer after the first etch-back process.

In an exemplary embodiment, after the third etch-back process, the thickness of the second oxide layer is greater than or equal to a first preset thickness, the first preset thickness being in a range of 450-550 angstroms.

In an exemplary embodiment, the forming an isolation oxide layer on a surface of the first trench based on a thermal oxidation process comprises: forming the isolation oxide layer on the surface of the first trench based on the thermal oxidation process to obtain a second trench formed by the isolation oxide layer surrounding the first trench; and forming a source conductor in the second trench; a top of the source conductor being lower than the top of the epitaxial layer.

In an exemplary embodiment, the forming an interlayer dielectric layer in the first trench to obtain a target semiconductor structure comprises: forming the interlayer dielectric layer in the first trench and on a surface of the hard mask layer; performing a planarization process on a surface of the substrate structure provided with the interlayer dielectric layer to remove the interlayer dielectric layer located on the hard mask layer and a portion of the hard mask layer; and removing the hard mask layer, the first oxide layer and a portion of the interlayer dielectric layer to make a top of the interlayer dielectric layer being lower than the top of the epitaxial layer and the interlayer dielectric layer cover an end portion of the source conductor.

In an exemplary embodiment, in the target semiconductor structure, an angle between a top of the isolation oxide layer and the side wall of the first trench is an obtuse angle.

In an exemplary embodiment, the thickness of the isolation oxide layer is in a range of 4000-9000 angstroms.

In another aspect, the present invention further discloses a semiconductor structure prepared based on the formation method described above.

In another aspect, the present invention further discloses a formation method of a semiconductor device, comprising after forming a target semiconductor structure, forming a gate; wherein the target semiconductor structure is prepared based on the formation method described above.

In another aspect, the present invention further discloses a semiconductor device prepared based on the formation method described above.

In another aspect, the present invention further discloses an electronic apparatus, comprising the semiconductor device described above.

The embodiments of the present invention provide the formation method of the semiconductor structure. The method specifically involves performing two etch-back processes on the hard mask layer of the substrate structure having the first trench, and the thermal oxidation process is employed to form the isolation oxide layer on the surface of the first trench between the two etch-back processes of the hard mask layer. This approach, which directly utilizes a formation process to form the isolation oxide layer, ensures film uniformity. Compared with conventional composite processes of the formation method of the isolation oxide layer, this method significantly reduces film stress. Furthermore, by performing two etch-back processes on the hard mask layer, i.e., first performing an etch-back process before forming the isolation oxide layer to reduce the width of the hard mask layer, the subsequent bird beak effect in the isolation oxide layer is mitigated, and performing an etch-back process on the hard mask layer again after forming the isolation oxide layer to make the side edge of the hard mask layer flush with the side wall of the first trench, thereby minimizing the impact of the eave structure of the hard mask layer on the filling quality of subsequent materials (e.g., the interlayer dielectric layer).

### BRIEF DESCRIPTION OF DRAWINGS

In order to more clearly illustrate the technical solutions in the embodiments of the present invention, the drawings required for use in the description of the embodiments will be briefly introduced below. Obviously, the drawings described below are only some embodiments of the present invention. For those having ordinary skills in the art, other drawings can be obtained based on these drawings without creative work.

FIG. 1 is a scanning electron microscope image of a semiconductor device according to the prior art, provided as Comparative Example 1;

FIG. 2 is a schematic flowchart of a formation method of a semiconductor structure according to the present invention;

FIG. 3 is a cross-sectional view of a substrate structure having a first trench according to the present invention;

FIG. 4 is a cross-sectional view of the substrate structure obtained after a first etch-back process according to the present invention;

FIG. 5 is a cross-sectional view of the substrate structure obtained after forming a source conductor according to the present invention;

FIG. 6 is a cross-sectional view of the substrate structure obtained after a third etch-back process according to the present invention;

FIG. 7 is a cross-sectional view of the substrate structure obtained after a second etch-back process according to the present invention;

FIG. 8 is a cross-sectional view of a target semiconductor structure according to the present invention;

FIG. 9 is a cross-sectional view of the substrate structure obtained after performing an etch-back process on an interlayer dielectric layer according to the present invention;

FIG. 10 is a scanning electron microscope image of another semiconductor device according to the prior art, provided as Comparative Example 2;

FIG. 11 is a scanning electron microscope image of yet another semiconductor device according to the prior art, provided as Comparative Example 3;

FIG. 12 is a scanning electron microscope image of the target semiconductor structure according to the present invention.

Reference Numerals.

1-Base layer; 2-Epitaxial layer; 3-First oxide layer; 4-Hard mask layer; 5-Second oxide layer; 6-First trench; 7-Isolation oxide layer; 8-Concave structure; 9-Second trench; 10-Source conductor; 11-Interlayer dielectric layer.

### DETAILED DESCRIPTION OF THE INVENTION

The technical solutions in the embodiments of the present invention will be described clearly and completely below in conjunction with the drawings in the embodiments of the present invention. Obviously, the described embodiments are only part of the embodiments of the present invention, rather than all of the embodiments. Based on the embodiments in the present invention, all other embodiments obtained by those having ordinary skills in the art without creative work are within the scope of the present invention.

The term “one embodiment” or “embodiment” as used herein refers to a specific feature, structure or characteristic that may be comprised in at least one implementation of the present invention. In the description of the present invention, it should be understood that the orientation or positional relationship indicated by the terms “upper”, “lower”, “top”, “bottom”, etc. is based on the orientation or positional relationship shown in the accompanying drawings, which is only for the convenience of describing the present invention and simplifying the description, rather than indicating or implying that the device or element referred to must have a specific orientation, be constructed and operated in a specific orientation, and therefore cannot be understood as a limitation of the present invention. In addition, the terms “first” and “second” are used only for descriptive purposes, and cannot be understood as indicating or implying relative importance or implicitly indicating the number of technical features indicated. Thus, the features defined as “first” and “second” may comprise one or more of the features explicitly or implicitly. Moreover, the terms “first”, “second”, etc. are used to distinguish similar objects, and are not necessarily used to describe a specific order or sequence. It should be understood that the data used in this way can be interchangeable where appropriate, so that the embodiments of the present invention described here can be implemented in an order other than those illustrated or described here.

When a numerical range is disclosed herein, the above range is considered to be continuous and comprises the minimum and maximum values of the range, as well as each value between such minimum and maximum values. Furthermore, when a range refers to an integer, each integer between the minimum and maximum values of the range is comprised. In addition, when multiple ranges are provided to describe features or characteristics, the ranges can be merged. In other words, unless otherwise indicated, all ranges disclosed herein should be understood to comprise any and all sub-ranges included therein. For example, a specified range from “1 to 10” should be considered to comprise any and all sub-ranges between a minimum of 1 and a maximum of 10. Exemplary sub-ranges of the range 1 to 10 include, but are not limited to, 1 to 6.1, 3.5 to 7.8, 5.5 to 10, etc.

The manufacturing process of a semiconductor integrated circuit usually involves the processing and formation of multiple types of semiconductor devices or multiple devices of the same type. Since the functions of these semiconductor devices may be different, in order to avoid crosstalk between the devices, it usually needs to set trenches between the devices. Or in a semiconductor device, in order to avoid the influence between different structures (e.g., side-by-side structures or stacked structures), trenches are also set and isolation materials are formed in the trenches as isolation layers. Such isolation materials can usually be silicon oxide or silicon oxide derivatives, such as one or more of silicon nitride, silicon oxynitride, silicon oxycarbide, amorphous carbon and silicon oxycarbonitride. The commonly used formation process is to first form a silicon oxide layer using a high-temperature thermal oxidation process, which can be called a thermal oxide layer (Pad OX, POX). However, in order to ensure the isolation effect, when a relatively thick thermal oxide layer is formed, the bird beak effect is easily caused, and there will also be an issue of hard mask eave, resulting in quality defects (e.g. the presence of filling voids) in the subsequent material layer, which in turn affects the performance of the device.

The bird beak effect is a phenomenon in a local oxidation (LOCOS) process. It occurs at the edge of the oxide layer formed on a silicon wafer. In the LOCOS process, in order to isolate different devices, a layer of silicon dioxide needs to be grown on the silicon wafer. The oxidation process causes volume expansion at the interface between the oxide layer and the silicon wafer. When silicon is oxidized to form silicon dioxide, the volume increases. This volume expansion causes the edge of the oxide layer to push outward, forming a shape similar to a bird beak, which is the so-called “bird beak effect”. The bird beak effect causes the actual isolation region to be larger than the expected, which limits the further reduction of the device size, affects the integration and performance of the integrated circuit, and may also cause uneven electric field intensity, affecting the reliability and long-term stability of the device.

In order to avoid the above defects, the existing scheme usually adopts the combination of the thermal oxidation process and other deposition processes to make the thickness of the thermal oxide layer thinner (e.g., less than 2000 angstroms), and then uses chemical vapor deposition (CVD) or plasma enhanced chemical vapor deposition (PECVD) to form an oxide layer, thereby forming a composite oxide layer formed by the thermal oxidation process + the deposition process. But obviously, the formation steps of this scheme are more complicated, and this composite material layer is also prone to film stress, which affects the performance of the semiconductor device.

In order to explain the above problem more clearly, the manufacturing process of a shield gate trench-metal-oxide-semiconductor field-effect transistor (SGT-MOSFET), namely an SGT-MOS device, is taken as an example below.

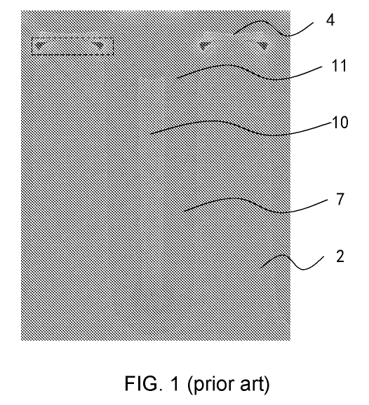

As a power device, the SGT-MOS device has the characteristics of high breakdown voltage, low on-resistance and fast switching speed, and can be applied to power circuits, motor drives, home appliances and other application fields. The SGT-MOS device usually comprises a gate located in an upper half of the trench and a source located in a lower half of the trench, and an isolation oxide layer 7 is provided between the gate and the source. The manufacturing process of the SGT-MOS device mainly involves the formation of the trench, the source, the gate, the isolation oxide layer 7, etc. For details, please refer to FIG. 1, which shows a scanning electron microscope image of an exemplary conventional semiconductor device. A mask layer may be first formed on a substrate (specifically, the substrate may comprise a base layer and an epitaxial layer 2 located on the base layer). The mask layer is specifically a composite layer structure, such as a three-layer composite structure of an oxide layer-hard mask layer-oxide layer. A material of a hard mask layer 4 may be silicon nitride, and the mask layer may be a SiO2 -SiN-SiO2 structure, which is also referred to as an ONO structure. Then, a layer of photoresist is formed on the mask layer, and the mask layer is patterned by photolithography, then the photoresist is removed, and the substrate is etched with a pattern defined by the mask layer to form a trench. Subsequently, the isolation oxide layer 7 is formed in the trench using a thermal oxidation process or a composite process directly, a first layer of polysilicon fills in the trench, and an etch-back process is performed to form a source conductor 10 (i.e., the source), then the isolation oxide layer 7 is deposited, and polysilicon is deposited and etched to form a gate. Finally, the subsequent processes such as body ion injection, source ion injection, or the like, are performed. When the isolation oxide layer 7 is formed in the trench using the thermal oxidation process directly, the bird beak effect as shown in a dotted box of FIG. 1 is formed, and eaves of the hard mask layer 4 are also generated, which in turn affects the quality defects (e.g. the presence of filling voids) of the subsequently formed material layer. When the isolation oxide layer 7 is formed using the composite process, although the influence of the above defects can be reduced, the formation steps are relatively complicated, and this composite material layer is also prone to film stress, which affects the performance of the semiconductor device.

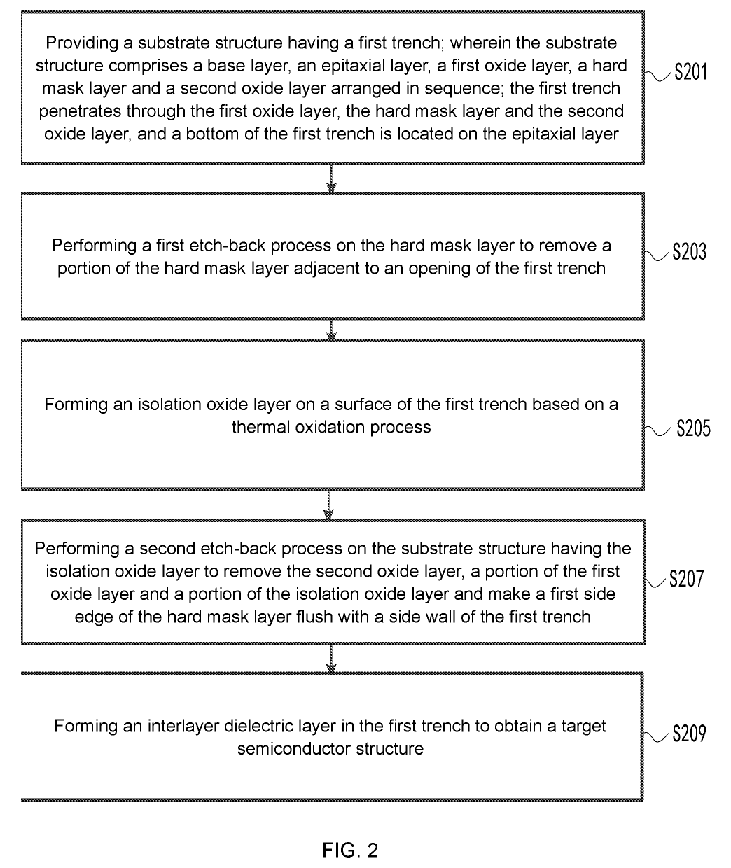

To this end, please refer to FIG. 2, which is a schematic flowchart of a formation method of a semiconductor structure according to the present invention. The formation method of the semiconductor structure provided in the embodiments of the present invention may comprise the following steps:

S201: providing a substrate structure having a first trench; wherein the substrate structure comprises a base layer, an epitaxial layer, a first oxide layer, a hard mask layer and a second oxide layer arranged in sequence; the first trench penetrates through the first oxide layer, the hard mask layer and the second oxide layer, and a bottom of the first trench is located on the epitaxial layer.

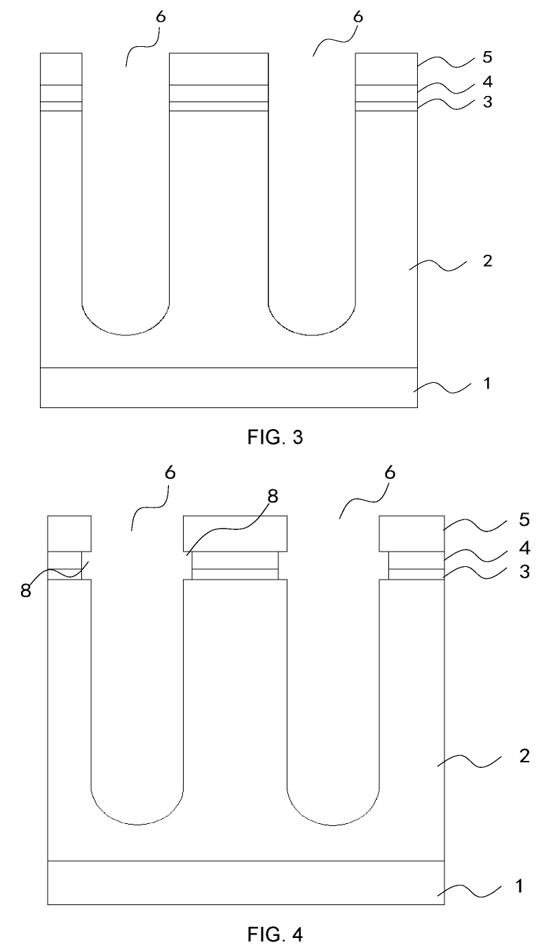

Exemplarily, the step S201 specifically comprises: providing a base layer 1 (see FIG. 3), a material of the base layer 1 specifically being at least one of silicon or silicon on insulator (SOI), etc. In the embodiments of the present invention, the base layer 1 may be a monocrystalline silicon substrate.

An epitaxial layer 2 is formed on the base layer 1. Optionally, the epitaxial layer 2 is specifically formed by an epitaxial growth process, and may be a homogeneous epitaxial layer, such as being able to continue to grow along a lattice direction of the base layer 1 to form the epitaxial layer 2, or a heterogeneous epitaxial layer, and a specific growth temperature may be the same as an existing process, or may be adaptively adjusted. Optionally, the epitaxial layer 2 is formed by chemical vapor deposition (CVD), physical vapor deposition (PVD), atomic layer deposition (ALD) or other deposition methods.

A first oxide layer 3, a hard mask layer 4, and a second oxide layer 5 are sequentially deposited on the epitaxial layer 2. Optionally, the first oxide layer 3 and the second oxide layer 5 may both be silicon oxide, the first oxide layer 3 may be formed by the thermal oxidation process, the second oxide layer 5 may be formed by the plasma chemical vapor deposition process, and the hard mask layer 4 may specifically be silicon nitride and may be formed by the CVD, such as plasma enhanced CVD (PECVD), high density plasma CVD, (HDPCVD), sub atmospheric CVD, (SACVD), low pressure CVD (LPCVD), atomic layer deposition (ALD), plasma enhanced atomic layer deposition (PEALD), or other types of chemical vapor deposition processes. In the embodiments of the present invention, a silicon nitride material may be formed on the first oxide layer 3 by the PECVD process as the hard mask layer 4.

A thickness of the second oxide layer 5 is greater than a thickness of the first oxide layer 3. Optionally, the thickness of the first oxide layer 3 may be in a range of 100 to 300 angstroms, and an exemplary thickness of the first oxide layer 3 may be 100 angstroms, 120 angstroms, 140 angstroms, 160 angstroms, 180 angstroms, 200 angstroms, 220 angstroms, 240 angstroms, 260 angstroms, 280 angstroms, or 300 angstroms. The thickness of the second oxide layer 5 may be in a range of 1700-3000 angstroms, and an exemplary thickness of the second oxide layer 5 may be 1700 angstroms, 1900 angstroms, 2100 angstroms, 2300 angstroms, 2500 angstroms, 2700 angstroms, 2900 angstroms, or 3000 angstroms. In fact, the thicknesses of the first oxide layer 3 and the thickness of the second oxide layer 5 are not limited to the above exemplary thicknesses, and can be adaptively adjusted as needed.

The mask layer composed of the first oxide layer 3, the hard mask layer 4 and the second oxide layer 5 is patterned to form an etching window, and the epitaxial layer 2 is etched to a preset depth based on the etching window to form a first trench 6, and obtain a structure as shown in FIG. 3. Optionally, the specific process of patterning the mask layer may comprise: first coating a photoresist on the second oxide layer 5 and patterning the photoresist to expose the second oxide layer 5 in a partial region, and etching the mask layer based on the patterned photoresist to form a patterned mask layer. Optionally, the hard mask layer 4 may be etched by a wet etching process, such as a phosphoric acid wet etching process. The first oxide layer 3 and the second oxide layer 5 may also be etched by the wet etching process. Optionally, the epitaxial layer 2 may be etched by the wet etching process or a dry etching process, wherein the dry etching process includes but is not limited to at least one of ion milling etching, plasma etching, reactive ion etching and laser ablation.

The first trench 6 may be a deep trench or a shallow trench, which is selected according to the performance requirements of the device to be manufactured. Generally, a width of a typical deep trench is between 65nm and 0.5μm, and a depth is between 2 and 5nm. In the embodiments of the present invention, the first trench 6 is a deep trench.

In the embodiments of the present invention, the formation of multiple SGT-MOS devices is taken as an example for explanation. For example, two SGT-MOS devices may be formed. In fact, the present solution is also applicable to the formation of single or array SGT-MOS devices, as well as other integrated circuits that are compatible with the steps S201-S209 process.

S203: performing a first etch-back process on the hard mask layer to remove a portion of the hard mask layer adjacent to an opening of the first trench.

In an exemplary embodiment, after the first etch-back process is performed, a first side edge of the hard mask layer 4 and a second side edge of the first oxide layer 3 are recessed inward relative to an inner wall of the first trench 6 to expose a partial region of a top of the epitaxial layer 2, and a structure as shown in FIG. 4 can be obtained. The first side edge and the second side edge are a side edge of the hard mask layer 4 and the first oxide layer 3 close to the inner wall of the first trench 6, respectively. Specifically, after the first etch-back process is performed, a bottom of the second oxide layer 5, the first side edge of the hard mask layer 4, the second side edge of the first oxide layer 3 and the top of the epitaxial layer 2 can form a concave structure 8 as shown in FIG. 4. By first performing a small amount of etch-back on the hard mask layer 4 in the mask layer, a small portion of the top region of the epitaxial layer 2 can be exposed at the opening of the first trench 6, which is conducive to the subsequent isolation oxide layer 7 to form an unclosed trench contour during growth. Optionally, the hard mask layer 4 may be etched laterally by the wet etching process.

Exemplarily, an etching amount of the hard mask layer 4 in the first etch-back process is in a range of 600-1500 angstroms. An exemplary etching amount of the first etch-back process of the hard mask layer 4 is 600 angstroms, 700 angstroms, 800 angstroms, 900 angstroms, 1000 angstroms, 1100 angstroms, 1200 angstroms, 1300 angstroms, 1400 angstroms or 1500 angstroms; the width of the exposed top of the epitaxial layer 2 is in a range of 0.03 to 0.1 microns, and an exemplary width of the exposed region of the top of the epitaxial layer 2 after the first etch-back process of the hard mask layer 4 is 0.03 microns, 0.035 microns, 0.04 microns, 0.045 microns, 0.05 microns, 0.055 microns, 0.06 microns, 0.07 microns, 0.08 microns, 0.09 microns or 0.1 microns. In fact, the specific etching amount and the width of the exposed region of the epitaxial layer 2 are not limited to the specific values of the above examples, and can be adjusted and determined according to actual processing conditions.

S205: forming an isolation oxide layer on a surface of the first trench based on a thermal oxidation process.

In an exemplary embodiment, the thickness of the isolation oxide layer 7 is in a range of 4000-9000 angstroms. Obviously, compared with the thickness (e.g., less than 2000 angstroms) of the thermal oxide layer in the composite process, the thermal oxide layer formed by the direct thermal oxide process in the present invention does not need to be composited with other process materials, thereby reducing the impact of film stress on the subsequent processes and devices.

Exemplarily, step S205 may specifically comprise: forming the thermal oxide layer on the surface of the first trench 6 and the surface of the second oxide layer 5 based on the thermal oxidation process to obtain the isolation oxide layer 7 so as to achieve an isolation effect.

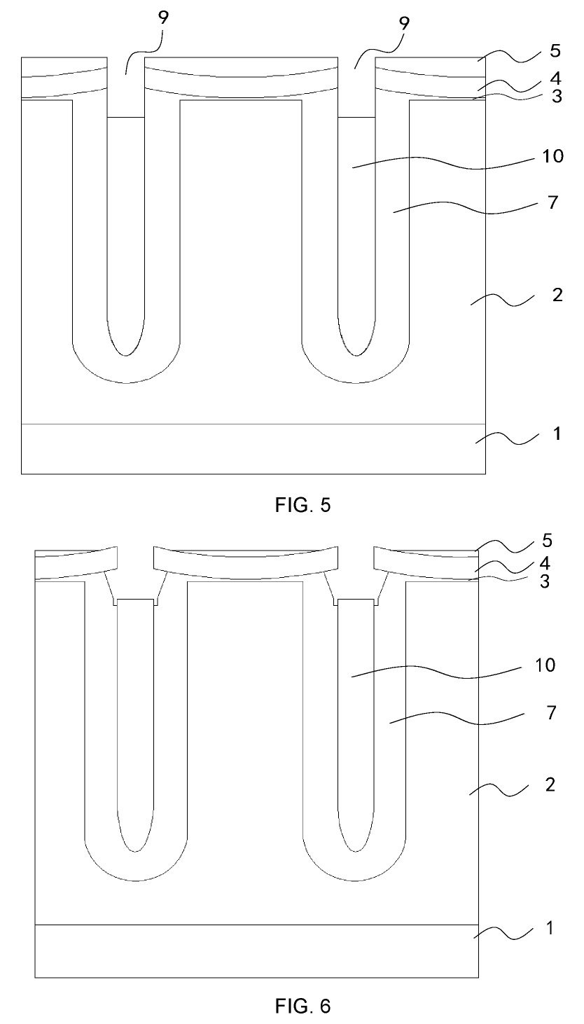

In the embodiments of the present invention, when it is applied to the SGT-MOS device, after the step S205 and before the following step S207, it also comprises the formation of the source conductor 10. Therefore, the step S205 may also be explained as: forming the isolation oxide layer 7 on the surface of the first trench 6 based on the thermal oxidation process to obtain a second trench 9 formed by the isolation oxide layer 7 surrounding the first trench 6; forming the source conductor 10 in the second trench 9 to obtain a structure as shown in FIG. 5; a top of the source conductor 10 being lower than the top of the epitaxial layer 2.

After forming the second trench 9, a source material may be formed on a surface of the second trench 9 and on the top of the isolation oxide layer 7, and the source conductor 10 may be formed in the second trench 9 by performing successive planarization and etch-back on the source material layer.

In the embodiments of the present invention, a layer of source material may cover an upper surface of the isolation oxide layer 7 by the vapor deposition process, the source material includes but is not limited to polysilicon. Then, the excess source material may be removed using a chemical mechanical polishing process. Specifically, the source material is polished to the isolation oxide layer 7 to stop, i.e., the source material on the isolation oxide layer 7 is removed. The source material in the second trench 9 is etched back by the dry etching process so that the source material in the second trench 9 is lower than the top of the epitaxial layer 2.

Since the isolation oxide layer 7 is relatively thick, it takes a long time to subsequently etch back the hard mask layer 4. In order to shorten the subsequent etch-back time of the hard mask layer 4, the oxide layer may be etched back appropriately to expose an end portion of the hard mask layer 4 to increase a contact area between the hard mask layer 4 and an etching solution and accelerate the etch-back speed of the hard mask. Therefore, in an exemplary embodiment, before performing the second etch-back process on the substrate structure having the isolation oxide layer, the method further comprises: performing a third etch-back process on the substrate structure having the isolation oxide layer 7 to expose the end portion of the hard mask layer 4, thereby obtaining a structure as shown in FIG. 6.

Exemplarily, after the third etch-back process is performed, the thickness of the second oxide layer 5 is less than the thickness of the second oxide layer 5 after the first etch-back process, i.e., during the third etch-back process, the second oxide layer 5 is also partially etched, but a portion of the thickness of the second oxide layer 5 still needs to be retained. Optionally, after the third etch-back process is performed, the thickness of the second oxide layer 5 is greater than or equal to a first preset thickness, the first preset thickness being in a range of 400-550 angstroms, and an exemplary first preset thickness may be 400 angstroms, 420 angstroms, 440 angstroms, 460 angstroms, 480 angstroms, 500 angstroms, 520 angstroms, 540 angstroms or 550 angstroms. Thus, the process window of the fluctuation of the previous layer and the fluctuation of the etching rate of the current process step can be guaranteed. The etching amount of the third etch-back process can be adjusted according to the remaining thickness of the second oxide layer 5 of the previous layer, the exposed size of the end portion of the hard mask layer 4, and the size of an obtuse angle required to be formed between the isolation oxide layer 7 and the inner wall of the first trench 6. A maximum etching amount of the third etch-back process is determined by the remaining thickness of the second oxide layer 5 of the previous layer after a minimum remaining amount is defined, and the etching amount of the third etch-back process affects the size of the exposed area of the end portion of the hard mask layer 4, and the exposed area affects the etching amount of the hard mask etch-back, and also affects the size of the obtuse angle formed subsequently. Generally, the larger the etching amount of the third etch-back process, the larger the obtuse angle accordingly, and there is a certain adjustment relationship, which leaves enough process window for the subsequent deposition of an interlayer dielectric layer 11.

Based on the above, before the subsequent step S207, i.e., before the substrate structure having the isolation oxide layer 7 is subjected to the second etch-back process, a partial oxide layer in the semiconductor structure is first etched back, so that the exposed area of the end portion of the hard mask layer 4 can be increased. If the partial oxide layer is not etched first, it can be seen from FIG. 5 that the hard mask layer 4 is located between the two oxide layers, and the exposed area of the two ends of the hard mask layer 4 is very small, and it takes a long time to directly etch the hard mask. Therefore, an appropriate amount of etch-back on the oxide layer is performed based on the characteristic of the second oxide layer 5 being thin at both ends and thick in the middle to remove the second oxide layer 5 located above the end portion of the hard mask layer 4 and the first oxide layer 3 located below, so that more region of the end portion of the hard mask layer 4 is exposed, and when the hard mask layer 4 is etched later, its etching speed can be greatly improved. Optionally, a ratio of the etching speed of the hard mask layer 4 to the etching speed of the oxide layer is (10-20): 1.

In addition, since the hard mask layer 4 forms an arc structure after the isolation oxide layer 7 is formed, under the blocking of the hard mask layer 4, when a portion of the oxide layer is etched back, the side wall of the oxide layer forms a contour with a certain inclination angle, i.e., slightly higher at both ends and slightly lower in the middle. This inclined contour is inherited by the subsequent process of etching the oxide layer, so that the thickness of the oxide layer formed at the corner is thicker, thereby increasing the breakdown voltage of the device.

In the embodiment of the present invention, during the third etch-back process of the oxide layer in the structure formed in the step S205, a partial region of the first oxide layer 3, a partial region of the second oxide layer 5, and a partial region of the isolation oxide layer 7 at the opening of the second trench 9 are etched and removed. The specific etching amount is determined based on the region of the end portion of the hard mask layer 4 that needs to be exposed. After the third etch-back process is performed, the top of the source conductor 10 may be exposed or not exposed, which is not limited here.

S207: performing a second etch-back process on the substrate structure having the isolation oxide layer to remove the second oxide layer, a portion of the first oxide layer and a portion of the isolation oxide layer and make the first side edge of the hard mask layer flush with a side wall of the first trench.

In the embodiments of the present invention, the second etch-back process of the step S207 specifically comprises etch-back of the hard mask layer 4 and etch-back of the oxide layer. Through the second etch-back process of the hard mask layer 4, the side edge of the hard mask layer 4 can be flush with the side wall of the first trench 6, and the second etch-back process of the oxide layer can be specifically etch-back of the first oxide layer 3, the second oxide layer 5 and the isolation oxide layer 7, so as to remove the second oxide layer 5, a portion of the first oxide layer 3 and a portion of the isolation oxide layer 7.

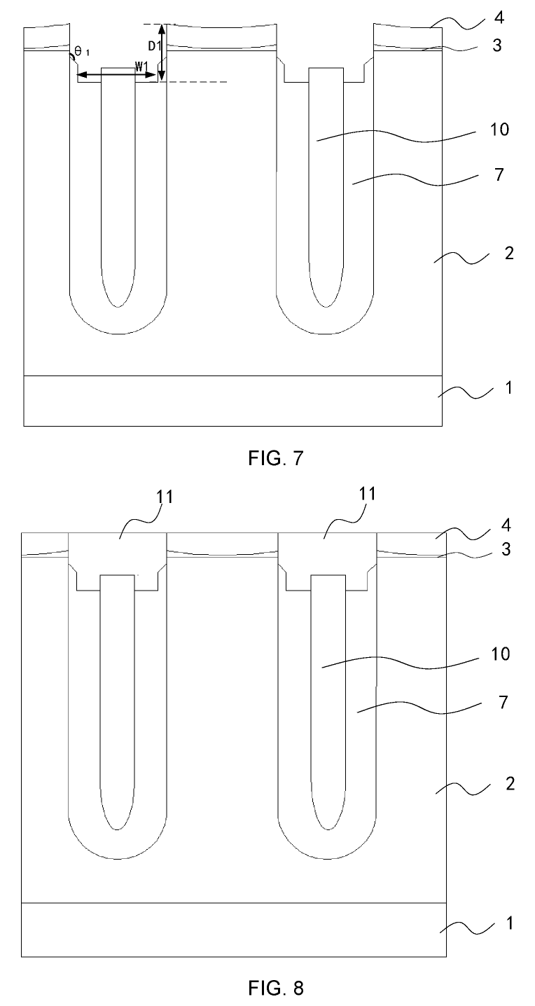

In an exemplary embodiment, the etching amount of the hard mask layer 4 by the first etch-back process is less than the etching amount of the hard mask layer 4 by the second etch-back process. That is, by first performing a small amount of etch-back on the hard mask layer 4 and then a large amount of etch-back on the hard mask layer 4, not only can the bird beak effect be effectively reduced, but also the side wall of the hard mask is made flush with the inner wall of the first trench 6 (see FIG. 7) by the second etch-back process, which can reduce the influence of the eaves of the hard mask layer 4 on the filling of subsequent material layers.

Exemplarily, the hard mask layer 4 may be laterally etched by the wet etching process. For example, the second etch-back process is performed on the hard mask layer 4 using the phosphoric acid wet etching process.

In the embodiments of the present invention, the substrate structure after the second etch-back process can specifically be a structure as shown in FIG. 7. After the second etch-back process is performed on the oxide layer in the substrate structure having the isolation oxide layer 7, all the second oxide layer 5 is removed, and an angle between the top of the isolation oxide layer 7 and the inner wall of the first trench 6 can be made an obtuse angle. That is, an angle between the isolation oxide layer 7 and the inner wall of the first trench 6 is θ1. The specific value of the obtuse angle is not limited here, as long as it can meet the requirements of subsequent steps.

Through the step S207, the deposition window of the subsequent deposition step can be further opened, thereby ensuring the formation quality of the dielectric layer subsequently deposited in the first trench 6. Optionally, after the second etch-back process is performed, the substrate structure as shown in FIG. 7 can be obtained, and a groove window at the end portion of the isolation oxide layer 7 can be further enlarged, and an aspect ratio of the groove window (i.e., W1/D1) can be within 2.5:1.

S209: forming an interlayer dielectric layer in the first trench to obtain a target semiconductor structure.

In an exemplary embodiment, the formation of the device is exemplified by taking the SGT-MOS device as an example for explanation. In this case, the step S209 can be specifically described as follows: forming the interlayer dielectric layer 11 in the first trench 6 and on the surface of the hard mask layer 4; planarizing the surface of the substrate structure provided with the interlayer dielectric layer 11 to remove the interlayer dielectric layer 11 on the hard mask layer 4 and a portion of the hard mask layer 4; removing the hard mask layer 4, the first oxide layer 3 and a portion of the interlayer dielectric layer 11 to make the top of the interlayer dielectric layer 11 lower than the top of the epitaxial layer 2 and the interlayer dielectric layer 11 cover the end portion of the source conductor 10, so as to obtain the target semiconductor structure as shown in FIG. 8.

Exemplarily, a layer of dielectric material may be formed on an inner surface of the first trench 6 and on the top of the hard mask layer 4 by a deposition process. The deposition process includes but is not limited to PECVD, HDPCVD, SACVD, LPCVD, ALD, PEALD, etc. In the embodiments of the present invention, a dielectric material is formed by the HDPCVD, and the dielectric material includes but is not limited to silicon oxide.

The dielectric material and the hard mask layer 4 are planarized to form a structure as shown in FIG. 8, so that the top surfaces of the dielectric material and the hard mask layer 4 are relatively flat. Specifically, the excess dielectric material and the warped hard mask layer 4 may be removed using the chemical mechanical polishing process to form the interlayer dielectric layer 11 in the first trench 6.

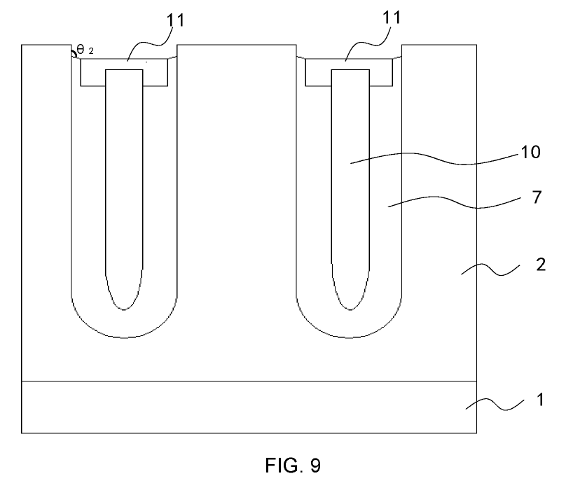

Then, the remaining hard mask layer 4 and the remaining first oxide layer 3 are removed, and the interlayer dielectric layer 11 is etched back at the same time, so as to obtain the structure shown in FIG. 9. At this time, since all the second oxide layer 5 is removed after the second etch-back process of the oxide layer in the substrate structure having the isolation oxide layer 7 and the angle between the top of the isolation oxide layer 7 and the inner wall of the first trench 6 can be made to be an obtuse angle by the above steps, i.e., the top of the isolation oxide layer 7 is an inclined structure. This feature will be inherited when the first oxide layer 3 and the interlayer dielectric layer 11 are further etched back, so that after the interlayer dielectric layer 11 is etched back, a structure in which the angle between the isolation oxide layer 7 and the inner wall of the first trench 6 is θ2 is formed. Specifically, θ2 may be 120°, and the specific value of θ2 is related to the size of the prepared device, and the top of the isolation oxide layer 7 and the top of the interlayer dielectric layer 11 form a concave structure, i.e., a structure being slightly higher at sides and slightly lower in the middle, and the specific height difference is related to the size of the prepared device.

In the manufacturing process of the SGT-MOS device, in addition to the above process steps, it also comprises gate formation, body region doping, source doping and other processes. For example, the gate formation process can be specifically carried out by continuing to form an epitaxial layer on the top of the structure shown in FIG. 9, which may be called a second epitaxial layer. The epitaxial layer in the substrate structure of the aforementioned step may be called a first epitaxial layer. Subsequently, a body region may be formed by performing ion doping on the second epitaxial layer. The second epitaxial layer may be specifically homoepitaxial or heteroepitaxial, which is not limited here. The second epitaxial layer is patterned to form a through hole penetrating through the second epitaxial layer, the through hole is connected to the first trench 6, and the widths of the through hole and the first trench 6 may be the same. Then a surface of the second epitaxial layer and the surface of the first trench 6 are covered with a gate dielectric layer. Specifically, an oxide layer is formed on the surface of the second epitaxial layer, a side wall of the through hole, the side wall of the first trench 6, the surface of the isolation oxide layer 7, and the surface of the interlayer dielectric layer 11 by the thermal oxidation process. At this time, the oxide layer and the interlayer dielectric layer 11 form an isolation layer for isolating the source conductor 10 and the gate. The gate dielectric layer is configured to isolate the epitaxial layer (comprising the first epitaxial layer and the second epitaxial layer) from the gate to prevent doping elements in the gate from diffusing into the epitaxial layer. A layer of gate material is covered on the gate dielectric layer, and the excess gate material and dielectric layer on the top of the second epitaxial layer are removed by the polishing process, so that the gate is located in the groove formed by the gate dielectric layer. The gate material may be polysilicon. The above gate formation process is only an exemplary scheme, and the present invention does not limit the gate formation process.

The embodiments of the present invention perform the second etch-back process on the oxide layer in the substrate structure having the isolation oxide layer 7, thereby opening a sufficient deposition window to allow the subsequent interlayer dielectric layer 11 to be normally filled, avoiding filling voids, and also making the top of the isolation oxide layer 7 form an obtuse angle with the side wall of the first trench 6. Subsequently, the interlayer dielectric layer 11 is filled in the first trench 6 and back etched, so that the oxide layer in the first trench 6 has a contour shape that is slightly lower in the middle and slightly higher on both sides, which is beneficial to increase the thickness of the gate dielectric layer at the corner, thereby improving the source-gate leakage performance.

In order to better illustrate the technical effect of the technical solution of the present invention, several comparative examples are used for illustration. The manufacturing method of the semiconductor device provided in Comparative Example 1 specifically comprises the following steps: first, providing a substrate structure having a first trench 6; wherein the substrate structure comprises a base layer 1, an epitaxial layer 2, a first oxide layer 3, a hard mask layer 4, and a second oxide layer 5 arranged in sequence from bottom to top; the first trench 6 penetrates through the first oxide layer 3, the hard mask layer 4, and the second oxide layer 5, and a bottom of the first trench 6 is located in the epitaxial layer 2; wherein the first oxide layer 3 and the second oxide layer 5 are both silicon oxide, and the hard mask layer 4 is silicon nitride. Subsequently, the hard mask layer 4 is subjected to a large amount of etch-back to remove a portion of the hard mask layer 4 adjacent to an opening of the first trench 6; an isolation oxide layer 7 is formed on a surface of the first trench 6 based on a thermal oxidation process, and a second trench 9 is obtained by the isolation oxide layer 7 surrounding the first trench 6; a source conductor 10 is formed in the second trench 9; the oxide layer in the structure of the aforementioned steps is then etched back to remove the second oxide layer 5, a portion of the first oxide layer 3 and a portion of the isolation oxide layer 7, and then an interlayer dielectric layer 11 is filled, specifically, an interlayer dielectric layer 11 is formed in the first trench 6; the source conductor 10 is located in a cavity formed by the isolation oxide layer 7 and the interlayer dielectric layer 11. In short, the manufacturing method provided in Comparative Example 1 is to perform a large amount of etch-back on the hard mask layer 4 only once before the growth of the isolation oxide layer 7, and no further etch-back is performed subsequently, which is equivalent to only performing the etch-back on the hard mask layer 4 in the step S207 of this scheme before filling the isolation oxide layer 7 to obtain the target semiconductor structure shown in FIG. 1. It can be seen that the structure obtained in the Comparative Example 1 has a serious bird beak phenomenon (a region shown by a dotted box in FIG. 1) after the growth of the isolation oxide layer 7, and there is a loss on the top of the epitaxial layer 2, the side wall contour of the epitaxial layer 2 is poor, and there is an abnormal filling of the interlayer dielectric layer 11 (e.g., the presence of filling voids), which affects the subsequent semiconductor processes.

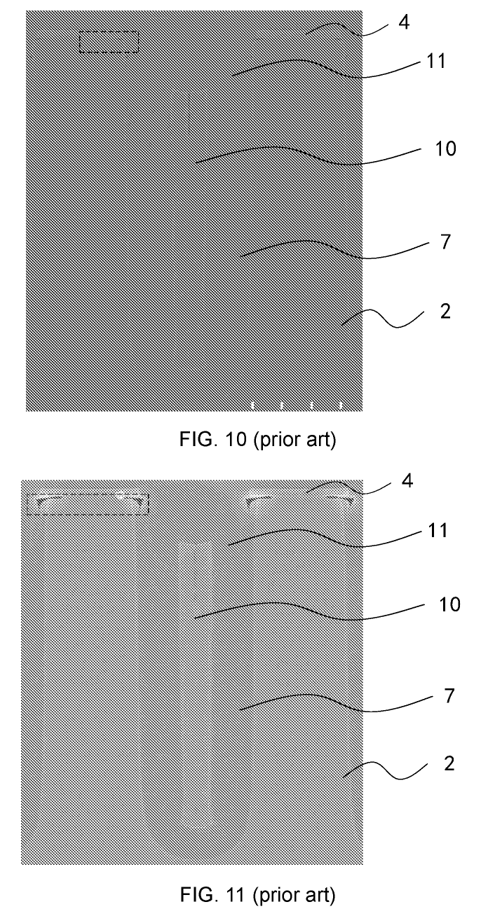

The manufacturing method of the semiconductor device provided in Comparative Example 2 specifically comprises the following steps: first, a substrate structure having a first trench 6 is provided; wherein the substrate structure comprises a base layer 1, an epitaxial layer 2, a first oxide layer 3, a hard mask layer 4 and a second oxide layer 5 arranged in sequence from bottom to top; the first trench 6 penetrates through the first oxide layer 3, the hard mask layer 4 and the second oxide layer 5, and a bottom of the first trench 6 is located at the epitaxial layer 2; wherein the first oxide layer 3 and the second oxide layer 5 are both silicon oxide, and the hard mask layer 4 is silicon nitride. An isolation oxide layer 7 is formed on a surface of the first trench 6 based on a thermal oxidation process, so as to obtain a second trench 9 formed by the isolation oxide layer 7 surrounding the first trench 6; a source conductor 10 is formed in the second trench 9; subsequently, a large amount of etch-back is performed on the hard mask layer 4 to remove a portion of the hard mask layer 4 adjacent to an opening of the first trench 6; the oxide layer in the structure of the aforementioned steps is then etched back to remove the second oxide layer 5, a portion of the first oxide layer 3 and a portion of the isolation oxide layer 7, and then the interlayer dielectric layer 11 is filled, specifically, an interlayer dielectric layer 11 is formed in the first trench 6; a source conductor 10 is located in a cavity formed by the isolation oxide layer 7 and the interlayer dielectric layer 11. In short, the manufacturing method provided in Comparative Example 2 is to perform a large amount of etch-back on the hard mask layer 4 only once before filling the interlayer dielectric layer 11, which is equivalent to only performing the etch-back on the hard mask layer 4 in the step S207 of this scheme before filling the interlayer dielectric layer 11 to obtain the target semiconductor structure shown in FIG. 10. It can be seen that the structure obtained in Comparative Example 2 has a slightly narrowed opening (a region shown by a dotted box in FIG. 10) of the first trench 6, and there are filling anomalies (e.g., the presence of filling voids) in the interlayer dielectric layer 11, which affects the subsequent semiconductor processes.

The manufacturing method of the semiconductor device provided in Comparative Example 3 specifically comprises the following steps: first, providing a substrate structure having a first trench 6; wherein the substrate structure comprises a base layer 1, an epitaxial layer 2, a first oxide layer 3, a hard mask layer 4 and a second oxide layer 5 arranged in sequence from bottom to top; the first trench 6 penetrates through the first oxide layer 3, the hard mask layer 4 and the second oxide layer 5, and a bottom of the first trench 6 is located at the epitaxial layer 2; wherein the first oxide layer 3 and the second oxide layer 5 are both silicon oxide, and the hard mask layer 4 is silicon nitride. Subsequently, the hard mask layer 4 is subjected to a small amount of etch-back to remove a portion of the hard mask layer 4 adjacent to an opening of the first trench 6; an isolation oxide layer 7 is formed on the surface of the first trench 6 based on a thermal oxidation process, so as to obtain a second trench 9 formed by the isolation oxide layer 7 surrounding the first trench 6; a source conductor 10 is formed in the second trench 9; the oxide layer in the structure of the aforementioned steps is then etched back to remove the second oxide layer 5, a portion of the first oxide layer 3 and a portion of the isolation oxide layer 7, and then the interlayer dielectric layer 11 is filled, specifically, an interlayer dielectric layer 11 is formed in the first trench 6; the source conductor 10 is located in a cavity formed by the isolation oxide layer 7 and the interlayer dielectric layer 11. In short, the manufacturing method provided in Comparative Example 3 is to only perform a small amount of etch-back on the hard mask layer 4 before the growth of the isolation oxide layer 7, which is equivalent to only performing the etch-back on the hard mask layer 4 in the step S203 of this scheme before filling the interlayer dielectric layer 11, and no further etch-back is performed subsequently, and the target semiconductor structure shown in FIG. 11 is obtained. It can be seen that the structure obtained in Comparative Example 3 has filling anomalies in the interlayer dielectric layer 11 (e.g. the presence of filling voids, such as a region shown by a dotted box in FIG. 11), which affects the subsequent semiconductor processes.

Based on the above Comparative Examples 1-3, it can be seen that after forming the first trench 6, only a small amount or a large amount of hard mask layer 4 being etched back once, or a large amount of hard mask layer 4 being etched back once before the isolation oxide layer 7 grows is not acceptable. After the first trench 6 is formed, only a small amount of hard mask layer 4 is etched back once, which causes serious eaves of the hard mask layer 4 after the isolation oxide layer 7 grows, and then causes filling anomalies of the subsequent interlayer dielectric layer 11. Alternatively, only a large amount of hard mask layer 4 is etched back once, which causes a serious bird beak phenomenon and causes the loss of the top region of the epitaxial layer 2, resulting in an abnormal side wall contour of the epitaxial layer 2. In addition, it is not acceptable to etch back a large amount of hard mask layer 4 before etch-back the isolation oxide layer 7, which causes the opening of the first trench 6 to be slightly narrowed, and the filling anomalies (e.g., the presence of filling voids) of the interlayer dielectric layer 11, affecting the subsequent semiconductor process processes.

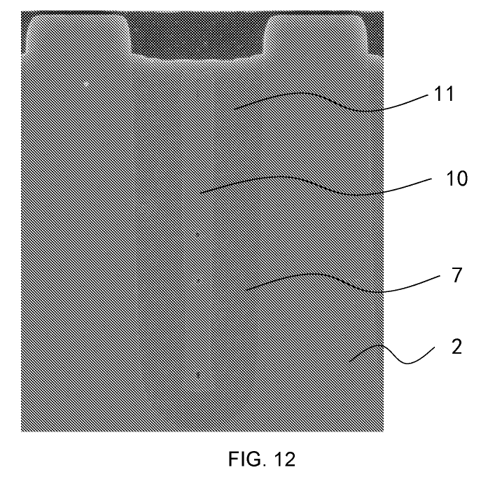

In this scheme, the hard mask layer 4 is etched back twice, and a large amount of etching and a small amount of etching are combined. That is, after forming the first trench 6, the hard mask layer 4 is first etched back with a small amount, then the isolation oxide layer 7 is formed based on the thermal oxidation process, and then the hard mask layer 4 is etched back with a large amount, and a portion of the oxide layer in the structure is removed, so that the side wall of the hard mask layer 4 is flush with the side wall of the first trench 6, then the interlayer dielectric layer 11 is filled, and the layer structure on the top of the epitaxial layer 2 and a portion of the interlayer dielectric layer 11 are etched away, making the interlayer dielectric layer 11 slightly lower than the top of the epitaxial layer 2. The scanning electron microscope image of the obtained structure is shown in FIG. 12. It can be seen that the semiconductor structure prepared by this method reduces the bird beak phenomenon, and the filling of the interlayer dielectric layer 11 is normal, the contour of the epitaxial layer 2 is good, and since the isolation oxide layer 7 is directly formed by the thermal oxidation process in this scheme, the film stress of the film layer is also reduced.

The embodiments of the present invention further provide a semiconductor structure, which is prepared based on the above formation method. The semiconductor structure comprises a base layer 1, an epitaxial layer 2, a first oxide layer 3 and a hard mask layer 4 arranged in sequence from bottom to top, and a first trench 6 penetrating through the first oxide layer 3 and the hard mask layer 4, and a bottom of the first trench 6 is located on the epitaxial layer 2, and the inner wall of the first trench 6 is provided with the isolation oxide layer 7 and the interlayer dielectric layer 11. Since the semiconductor structure is manufactured by the above formation method of the semiconductor structure, the hard mask layer 4 of the substrate structure having the first trench 6 is etched back twice, and the isolation oxide layer 7 is formed on the surface of the first trench 6 by the thermal oxidation process, not only the formed isolation oxide layer 7 will not generate film stress, but also its bird beak effect and the influence of the hard mask eaves on the filling quality of the interlayer dielectric layer 11 formed subsequently can be reduced.

The embodiments of the present invention further provide a formation method of a semiconductor device, which comprises: after forming a target semiconductor structure, forming a gate; wherein the target semiconductor structure is prepared based on the above formation method. The semiconductor device may be an SGT-MOS device, or other devices that need to be provided with the trench and the isolation oxide layer 7, which is not limited here. If the semiconductor device is an SGT-MOS device, it also needs to remove the remaining hard mask layer 4, the first oxide layer 3, etc. located on the epitaxial layer 2, and form the source conductor 10 in the trench formed by the isolation oxide layer 7, and form the gate, and other structures on the source conductor 10. Since the target semiconductor structure is manufactured by the above formation method of the semiconductor structure, i.e., by performing the etch-back on the hard mask layer 4 of the substrate structure having the first trench 6 twice, and forming the isolation oxide layer 7 on the surface of the first trench 6 using the thermal oxidation process, the formed isolation oxide layer 7 does not generate film stress, its bird beak effect and the influence of the hard mask eaves on the filling quality of the interlayer dielectric layer 11 formed subsequently can also be reduced. Therefore, the formation method of the semiconductor device comprising the formation method of the semiconductor structure has the same technical effect as above.

The embodiments of the present invention further provide a semiconductor device, which is prepared based on the above formation method. The semiconductor device may specifically be an SGT-MOS device, or other devices that need to be provided with the trench and the isolation oxide layer 7, which is not limited here. Since the formation of the semiconductor device comprises first forming the above semiconductor structure, the formation method of the semiconductor structure is to first perform the back-etch on the hard mask layer 4 of the substrate structure having the first trench 6 twice, and form the isolation oxide layer 7 on the surface of the first trench 6 using the thermal oxidation process, so that the formed isolation oxide layer 7 does not generate film stress, and its bird beak effect and the influence of the hard mask eaves on the filling quality of the interlayer dielectric layer 11 formed subsequently can be reduced. Therefore, the semiconductor device formed based on the formation method of the semiconductor structure has the same technical effect.

The embodiments of the present invention further provide an electronic apparatus, which comprises the above semiconductor device.

Specifically, the electronic apparatus comprises the semiconductor device and an electronic component connected to the semiconductor device. Since the formation of the semiconductor device comprises first forming the semiconductor structure, the formation method of the semiconductor structure is to first perform the etch-back on the hard mask layer 4 of the substrate structure having the first trench 6 twice, and form the isolation oxide layer 7 on the surface of the first trench 6 using the thermal oxidation process, the formed isolation oxide layer 7 does not generate film stress, and its bird beak effect and the influence of the hard mask eaves on the filling quality of the interlayer dielectric layer 11 formed subsequently can be reduced, so that the semiconductor device formed based on the formation method of the semiconductor structure has the same technical effect. The electronic component may be any electronic component such as a transistor.

The electronic apparatus may be any electronic product or apparatus such as a mobile phone, a tablet computer, a laptop computer, a netbook, a game console, a television, a VCD, a DVD, a navigator, a camera, a camcorder, a voice recorder, an MP3, an MP4, a PSP, etc., and may also be any intermediate product comprising the above semiconductor device.

It should be noted that the above sequence of the embodiments of the present invention is for description only and does not represent the advantages and disadvantages of the embodiments. The specific embodiments of this specification are described. Other embodiments are within the scope of the attached claims. In some cases, the actions or steps recorded in the claims can be performed in an order different from that in the embodiments and still achieve the desired results. In addition, the processes depicted in the drawings do not necessarily require the specific order or continuous order shown to achieve the desired results. In some embodiments, multitasking and parallel processing are also possible or may be advantageous.

Each embodiment in this specification is described in a progressive manner, and the same or similar parts between the embodiments can be referred to each other, and each embodiment focuses on the differences from other embodiments. In particular, for the device embodiment, since it is basically similar to the method embodiment, the description is relatively simple, and the relevant parts can be referred to the partial description of the method embodiment.

Those having ordinary skills in the art will understand that all or part of the steps to implement the above embodiments may be accomplished by hardware or by instructing related hardware through a program, and the program may be stored in a computer-readable storage medium, and the above-mentioned storage medium may be a read-only memory, a disk or an optical disk, etc.

The above description is only a preferred embodiment of the present invention and is not intended to limit the present invention. Any modifications, equivalent substitutions, improvements, etc. made within the spirit and principles of the present invention should be included in the scope of the present invention.

1. A formation method of a semiconductor structure, comprising:
providing a substrate structure having a first trench; wherein the substrate structure comprises a base layer, an epitaxial layer, a first oxide layer, a hard mask layer and a second oxide layer arranged in sequence; the first trench penetrates through the first oxide layer, the hard mask layer and the second oxide layer, and a bottom of the first trench is located on the epitaxial layer;
performing a first etch-back process on the hard mask layer to remove a portion of the hard mask layer adjacent to an opening of the first trench;
forming an isolation oxide layer on a surface of the first trench based on a thermal oxidation process;
performing a second etch-back process on the substrate structure having the isolation oxide layer to remove the second oxide layer, a portion of the first oxide layer and a portion of the isolation oxide layer and make a first side edge of the hard mask layer flush with a side wall of the first trench; and
forming an interlayer dielectric layer in the first trench to obtain a target semiconductor structure.

2. The formation method according to claim 1, characterized in that an etching amount of the hard mask layer in the first etch-back process is less than an etching amount of the hard mask layer in the second etch-back process.

3. The formation method according to claim 1, characterized in that after the first etch-back process, the first side edge of the hard mask layer and a second side edge of the first oxide layer are recessed inward relative to the side wall of the first trench to expose a partial region of a top of the epitaxial layer; wherein the first side edge and the second side edge are side edges of the hard mask layer and the first oxide layer close to the side wall of the first trench, respectively.

4. The formation method according to claim 1, characterized in that before performing the second etch-back process on the substrate structure having the isolation oxide layer, the method further comprises:
performing a third etch-back process on the substrate structure having the isolation oxide layer to expose an end portion of the hard mask layer.

5. The formation method according to claim 4, characterized in that a thickness of the second oxide layer after the third etch-back process is less than a thickness of the second oxide layer after the first etch-back process.

6. The formation method according to claim 5, characterized in that after the third etch-back process, the thickness of the second oxide layer is greater than or equal to a first preset thickness, the first preset thickness being in a range of 450-550 angstroms.

7. The formation method according to claim 1, characterized in that the forming an isolation oxide layer on a surface of the first trench based on a thermal oxidation process comprises:
forming the isolation oxide layer on the surface of the first trench based on the thermal oxidation process to obtain a second trench formed by the isolation oxide layer surrounding the first trench; and
forming a source conductor in the second trench, with a top of the source conductor being lower than a top of the epitaxial layer.

8. The formation method according to claim 7, characterized in that the forming an interlayer dielectric layer in the first trench to obtain a target semiconductor structure comprises:
forming the interlayer dielectric layer in the first trench and on a surface of the hard mask layer;
performing a planarization process on a surface of the substrate structure provided with the interlayer dielectric layer to remove the interlayer dielectric layer located on the hard mask layer and a portion of the hard mask layer; and
removing the hard mask layer, the first oxide layer and a portion of the interlayer dielectric layer to make a top of the interlayer dielectric layer being lower than the top of the epitaxial layer and the interlayer dielectric layer cover an end portion of the source conductor.

9. The formation method according to claim 1, characterized in that in the target semiconductor structure, an angle between a top of the isolation oxide layer and the side wall of the first trench is an obtuse angle.

10. The formation method according to claim 1, characterized in that a thickness of the isolation oxide layer is in a range of 4000-9000 angstroms.

11. A semiconductor structure, characterized by being prepared based on the formation method according to claim 1.

12. A formation method of a semiconductor device, comprising:
after forming a target semiconductor structure, forming a gate; wherein the target semiconductor structure is prepared based on the formation method according to claim 1.

13. A semiconductor device, characterized by being prepared based on the formation method according to claim 12.

14. An electronic apparatus, comprising the semiconductor device as claimed in claim 13.
